(19) United States
(12) Patent Application Publication
(10) Pub. No.: US 2019/0294295 A1
(43) Pub. Date: Sep. 26, 2019

(54) APPARATUS AND METHOD FOR REDUCING AMPLIFIER FEEDBACK CAPACITOR WITH BYPASS AMPLIFICATION STAGE

(71) Applicant: QUALCOMM Incorporated, San Diego, CA (US)

(72) Inventors: Zongyu Dong, San Jose, CA (US); Sameer Wadhwa, San Diego, CA (US); Shunxi Wang, Palo Alto, CA (US)

(21) Appl. No.: 15/926,728

(22) Filed: Mar. 20, 2018

(51) Int. Cl. G06F 3/041; H03F 3/21; H03F 3/45; H03F 3/213; H03F 1/02; G06F 3/044

(52) U.S. Cl. CPC G06F 3/0418; H03F 2203/45528; H03F 3/45215; H03F 3/213; H03F 1/0205; G06F 3/044; H03F 2200/267; H03F 2200/144; H03F 2200/165; H03F 2203/21157; H03F 2203/45031; H03F 2203/45032; H03F 2203/45116; H03F 2203/45526; H03F 2203/45512; H03F 3/211

(57) ABSTRACT

A touchscreen controller includes a set of transmitters for generating transmit signals applied to electrically-conductive transmit lines of a touchscreen panel, and a set of receivers configured to receive the signals via electrically-conductive receive lines that are capacitively coupled to the transmit lines. Each receiver includes an integrator to integrate the received current signal to generate an output voltage used for determining a location, if any, of a finger or object touching the panel. The integrator includes input and output amplification stages, and a feedback capacitor coupled between an input and output of the cascaded amplification stages. The capacitance of the feedback capacitor is configured so that the integrator achieves a desired rejection of a received jammer current signal. To reduce the size of the feedback capacitor, a bypass amplification stage is provided to steer away some of the input jammer current from the input of the integrator.

### FIELD

Aspects of the present disclosure relate generally to touchscreen controllers, and in particular, to an apparatus and method for reducing amplifier feedback capacitor with bypass amplification stage in receivers of a touchscreen controller.

### BACKGROUND

A touchscreen panel includes a set of electrically-conductive transmit lines formed on a first transparent layer and spaced apart along a first direction (e.g., vertical) and extending along a second direction (e.g., horizontal) orthogonal to the first direction. The touchscreen panel also includes a set of electrically-conductive receive lines formed on a second transparent layer and spaced apart along the second direction and extending along the first direction. A mutual capacitance exists between each pair of transmit-receive line at each intersection of the transmit and receive lines.

A set of transmit drivers generate a set of transmit signals applied to the set of transmit lines, respectively. A set of receivers receive a set of receive signals via the set of receive lines, wherein the receive signals are the transmit signals after propagating through the touchscreen panel via the transmit lines and the receive lines.

A finger or pointing object placed on the touchscreen panel affects the mutual capacitance at one or more transmit-receive line intersections. The effect on the mutual capacitance affects one or more of the received signals at the receivers. By determining which signals are affected, the location of the finger or pointing object may be ascertained. A processor, operating under a software program, may receive the detected location of the finger or pointing object, and may perform one or more defined operations based on such detection.

This disclosure relates to improvements to the set of receivers for generating signals for use in detecting the location of the finger or pointing object placed on the touchscreen panel.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

An aspect of the disclosure relates to an apparatus including a first amplification stage including a first input and a first output; a second amplification stage including a second input and a second output, wherein the second input is coupled to the first output of the first amplification stage; a feedback capacitor coupled between the second output of the second amplification stage and the first input of the first amplification stage; and a third amplification stage including a third input and a third output, wherein the third input is coupled to the first output of the first amplification stage, and the third output is coupled to the first input of the first amplification stage.

Another aspect of the disclosure relates to a method including integrating a first portion of an input current to generate an output voltage, and steering away a second portion of the input current to prevent the second portion from being integrated to form the output voltage.

Another aspect of the disclosure relates to apparatus including means for integrating a first portion of an input current to generate an output voltage; and means for steering away a second portion of the input current to prevent the second portion from being integrated to form the output voltage.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the description embodiments are intended to include all such aspects and their equivalents.

### BRIEF DESCRIPTION OF THE DRAWINGS

FIG. 1 illustrates a diagram of an exemplary touchscreen display in accordance with an aspect of the disclosure.

FIG. 2 illustrates a schematic diagram of an exemplary single transmit-receive channel of a touchscreen display in accordance with another aspect of the disclosure.

FIG. 3 illustrates a schematic diagram of an exemplary receiver in accordance with another aspect of the disclosure.

FIG. 4 illustrates a schematic diagram of another exemplary receiver in accordance with another aspect of the disclosure.

FIG. 5 illustrates a diagram of another exemplary touchscreen display in accordance with an aspect of the disclosure.

FIG. 6 illustrates a schematic diagram of another exemplary receiver in accordance with another aspect of the disclosure.

FIG. 7 illustrates a schematic diagram of yet another exemplary receiver in accordance with another aspect of the disclosure.

FIG. 8A illustrates a schematic diagram of exemplary amplifier in accordance with another aspect of the disclosure.

FIG. 8B illustrates a schematic diagram of an exemplary bypass amplification stage in accordance with another aspect of the disclosure.

FIG. 9 illustrates a flow diagram of an exemplary method of processing an input current signal in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

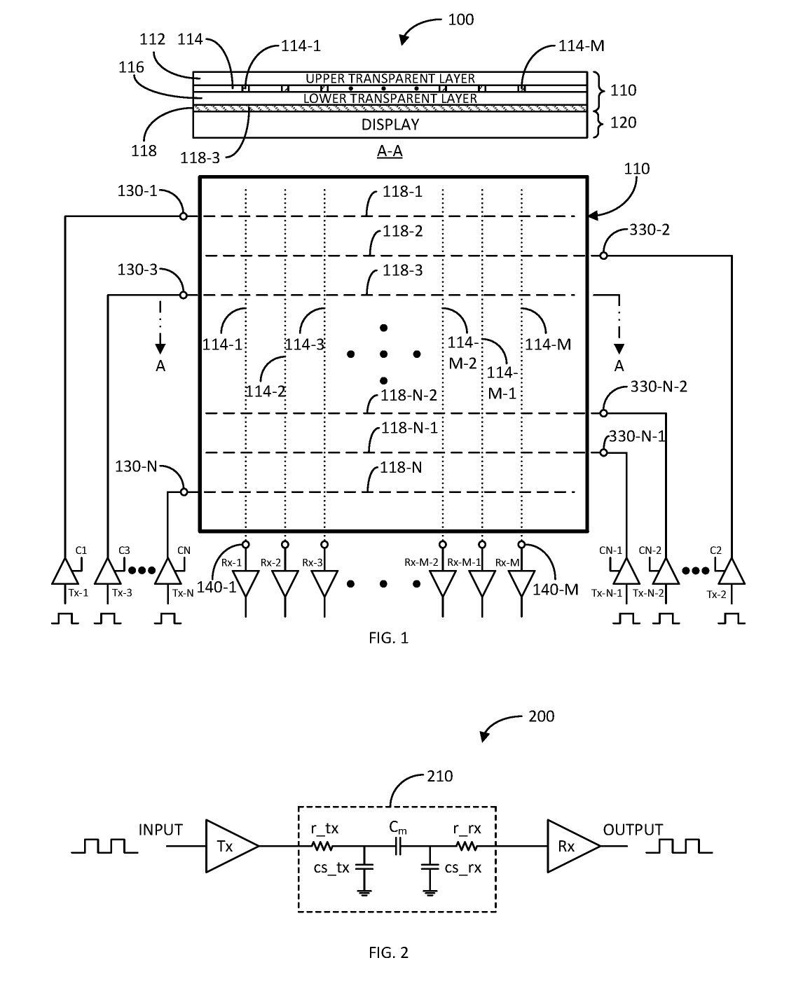

FIG. 1 illustrates a diagram of an exemplary touchscreen display 100 in accordance with an aspect of the disclosure. The touchscreen display 100 includes a touchscreen panel 110 disposed over a display 120, as illustrated in cross-sectional view A-A. The display 120 provides an image or video to a user, who may be positioned above in view A-A or in front of the drawing sheet in the non-cross-sectional view. The touchscreen panel 110 provides an indication (if any) of a location of a finger or pointing object (e.g., a stylus) that may be placed on the panel.

As seen in cross-sectional view A-A, the touchscreen panel 110 includes an upper transparent (e.g., glass) layer 112 disposed over a receive line layer 114, which, in turn, is disposed over a lower transparent (e.g., glass) layer 116, which, in turn, is disposed over a transmit line layer 118, which, in turn, is disposed over the display 120. It shall be understood that the touchscreen panel 110 is merely an example and may be configured to include more or less layers.

The transmit line layer 118 includes a set of horizontal, electrically-conductive transmit lines 118-1 to 118-N, which are uniformly spaced-apart along a vertical dimension of the touchscreen panel 110. The electrically-conductive transmit lines 118-1 to 118-N may include indium-tin-oxide to give them light transparency properties.

Similarly, the receive line layer 114 includes a set of vertical electrically-conductive receive lines 114-1 to 114-M, which are uniformly spaced-apart along a horizontal dimension of the touchscreen panel 110. The electrically-conductive receive lines 114-1 to 114-M may also include indium-tin-oxide to give them light transparency properties.

The touchscreen display 100 further includes a set of transmit drivers Tx-1 to Tx-N configured to generate a set of signals applied to the transmit lines 118-1 to 118-N of the touchscreen panel 110 via a set of electrodes 130-1 to 130-N, respectively. Additionally, the touchscreen display 100 includes a set of receivers Rx-1 to Rx-M configured to receive the set of signals transmitted by the set of transmit drivers Tx-1 to Tx-N via the set of receive lines 114-1 to 114-M and a set of electrodes 140-1 to 140-M, respectively. The receive lines 114-1 to 114-M are capacitively coupled to the transmit lines 118-1 to 118-N; allowing the set of signals to be routed from the transmit drivers Tx-1 to Tx-N to the receivers Rx-1 to Rx-M.

In operation, the transmit drivers Tx-1 to Tx-N may transmit the set of signals in a time-multiplexed or code-division multiplexed manner Each of the receivers Rx-1 to Rx-M receives the set of signals from the transmit drivers Tx-1 to Tx-N via the transmit lines 118-1 to 118-N and the receive lines 114-1 to 114-M. When a finger or object is placed on the touchscreen panel 110, the signal received by one or more receivers may be altered due to capacitive (electrostatic) interference of the finger or object. A controller (not shown) receives the signals outputted by the receivers Rx-1 to Rx-M, and is able to determine the location of the finger or object based on the received signals.

When there is no finger or object on the touchscreen panel 110 (e.g., no panel load), it is desirable that the signals received by the receivers Rx-1 to Rx-M be substantially the same in terms of amplitude, phase, and skew rate. As discussed further, this is because each receiver also receives an anti-phase or offset signal, which is combined with the signal received from the panel 110 to cause the receiver to output a mid-range voltage (e.g., substantially zero (0) Volt if the receiver is supplied by symmetrical voltages V+ and V−) when there is no finger or object detected by the receiver. This provides a desirable dynamic range for the receiver to better detect the signal when altered by a finger or object on the panel, as well as handle any jammer (e.g., unwanted signal and/or noise) that may be received.

FIG. 2 illustrates a schematic diagram of a single transmit-receive channel 200 of the touchscreen display 100 in accordance with another aspect of the disclosure. The channel 200 includes a transmit driver Tx, an equivalent circuit 210 associated with the touchscreen panel 110, and a receiver Rx.

The transmit driver Tx generates a pulsing or oscillating transmit signal for the touchscreen panel 210.

The touchscreen panel 210 includes a transmit line Tx Line, which may be represented as a series resistor r_tx and a shunt capacitor cs_tx. The panel 210 further includes a mutual capacitor Cm, which is the capacitance at the intersection between the transmit line Tx line and the receive line Rx associated with the particular channel 200. Further, the touchscreen panel 210 includes the receive line Rx Line, which may be represented as a series resistor r_rx and a shunt capacitor cs_rx.

The receiver Rx receives the transmit signal from the touchscreen panel 210 and processes the signal to generate an output signal.

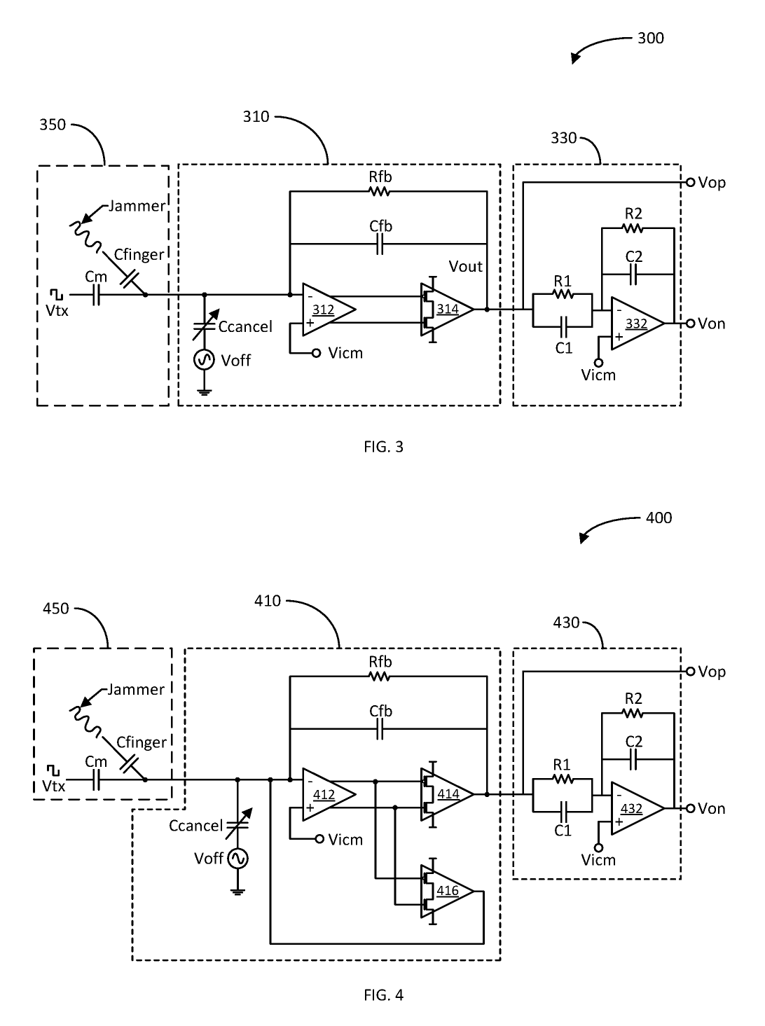

FIG. 3 illustrates a schematic diagram of an exemplary receiver 300 in accordance with another aspect of the disclosure. The receiver 300 may be an exemplary detailed implementation of any of the receivers Rx-1 to Rx-M of touchscreen display 100. As illustrated, the receiver 300 receives a signal from a touchscreen panel 350, which includes a mutual capacitance Cm. As illustrated, when the touchscreen panel 350 is touched by a finger, stylus, or other object, an additional capacitance (referred to herein as “Cfinger”) is introduced into the panel circuit. Via the additional capacitance Cfinger, an unwanted signal and/or noise (referred to herein as a “jammer”) may be introduced into the receiver 300.

The receiver 300 includes an amplifier 310 configured as an integrator. The amplifier 310 includes an input amplification stage 312 and an output amplification stage 314. The input and output amplification stages 312 and 314 may collectively be configured as a class AB amplifier. In this example, the input amplification stage 312 includes an output coupled to an input of the output amplification stage 314. The amplifier 310 further includes a feedback network including feedback resistor Rfb and feedback capacitor Cfb coupled in parallel between an output of the output amplification stage 314 and a negative input of the input amplification stage 312.

The negative input of the input amplification stage 312 is configured to receive the transmit signal Vtx via the mutual capacitance Cm of the touchscreen panel 350, as well as a jammer via a capacitance Cfinger resulting from a user's interaction with the panel.

The negative input of the input amplification stage 312 also receives an offset voltage Voff via a variable cancellation capacitor Ccancel. The capacitance of the cancellation capacitor Ccancel may be adjusted so that it is substantially the same as the mutual capacitance of the touchscreen panel. The offset voltage Voff is a pulsing or oscillating signal that is configured to have an anti-phase (e.g., substantially 180 degrees) with respect to the transmit signal Vtx. Thus, the received signal from the panel 350 and the signal from the offset voltage Voff at the negative input of the input amplification stage 312 substantially cancels out when the touchscreen panel 350 is not being touched (i.e., when there is no load on the panel). The reason for this is to set the amplitude of the output voltage Vout of the amplifier 310 (when there is no finger or object placed on the panel) to midrange (e.g., ˜0V) of the dynamic range (e.g., ±1.8V) of the output voltage Vout. This allows the amplifier 310 to generate a positive or negative delta voltage when a finger or object is placed on the panel, as well as deal with any jammer introduced into the input of the amplifier 310 via the finger or object without going into saturation. A common mode voltage Vicm, applied to a positive input of the input amplification stage 312, is for setting the common mode voltage of the output voltage Vout of the amplifier 310.

The receiver 300 further includes an output circuit 330 for generating an output differential signal by generating a negative component Von of the differential signal from the output voltage Vout of the amplifier 310. The output voltage Vout of the amplifier 310 serves as the positive component Vop of the differential signal. The output circuit 330 includes an input circuit including resistor R1 coupled in parallel with capacitor C1 between the output of the amplifier 310 and a negative input of an operational amplifier 332. The operational amplifier 332 includes a positive input configured to receive a voltage Vicm for setting a common mode voltage of the negative component Von of the differential signal. The operational amplifier 332 is further configured as an integrator including feedback resistor R2 and feedback capacitor C2 coupled in parallel between the output and negative input of the operational amplifier. The negative component of the output differential signal is produced at the output of the operational amplifier 332.

In operation, when a user touches the touchscreen panel 350, the user's body acts as a capacitor, represented as Cfinger in the diagram. The user's finger or pointing object may also introduce a jammer into the input of the receiver 300, which may have a relatively high amplitude (e.g., 40 Volts peak-to-peak (40 Vpp)). Accordingly, one of the functions of the amplifier 310 is to reduce the impact of the jammer on the output voltage Vout of the amplifier.

With regard to the jammer, the amplifier 310 has a gain given by Cfinger/Cfb. If, for example, the jammer has a maximum amplitude of 40 Vpp, and the amplifier 310 is operated between ±1.8V supply voltage, it may be desirable to set the gain of the amplifier to be, for example, 1/40 to limit the output voltage Vout due to a jammer to an amplitude of 1V to prevent saturation of the amplifier. If Cfinger is 1 picofarad (pf), then to achieve such a gain, the feedback capacitor Cfb has to have a capacitance of 40 pf. Such capacitance (e.g., 40 pf) requires significant amount of IC footprint to implement the capacitor Cfb as a metal-insulator-metal (MIM) or metal-oxide-metal (MOM) type capacitor. A reason for using a MIM or MOM capacitor instead of a metal oxide semiconductor capacitor (MOSCAP) is because there is a linearity performance requirement to reduce folded noise due to non-linearity of the amplifier 310.

Furthermore, to achieve a desired bandwidth for the amplifier 310, the power consumption of the output amplification stage 314 should be a function of the feedback capacitance Cfb. Thus, if the feedback capacitor Cfb is large to achieve the desired gain, then the power consumption of the output amplification stage 314 is large to achieve the desired bandwidth.

In summary, a touchscreen controller includes receivers each having an amplifier including an input amplification stage, an output amplification stage, and a bypass amplification stage. The bypass amplification stage is configured to steer away current associated with the jammer from the input of the first amplification stage. This results in a decrease in the power of the jammer at the output of the amplifier due to this current steering.

As a result, the feedback capacitor Cfb can be made smaller to save significant IC footprint as the gain of the amplifier can be higher to achieve the same jammer rejection. Additionally, the power consumption of the output amplification stage of the amplifier may be reduced due to the smaller capacitance of the feedback capacitor Cfb.

FIG. 4 illustrates a schematic diagram of an exemplary receiver 400 in accordance with another aspect of the disclosure. The receiver 400 may be an exemplary detailed implementation of any of the receivers Rx-1 to Rx-M of touchscreen display 100 previously discussed. The receiver 400 includes an amplifier 410 and an output circuit 430. The receiver 400 is configured to receive a signal from a touchscreen panel 450 based on a transmit signal Vtx. The representation of the touchscreen panel 450 and the output circuit 430 including operational amplifier 432 are similar to that of receiver 300 previously discussed in detail.

Similar to the amplifier 310, the amplifier 410 includes an input amplification stage 412 and an output amplification stage 414. However, in the case of amplifier 410, it further includes a bypass amplification stage 416. The bypass amplification stage 416 is coupled in parallel with the output amplification stage 414. That is, the output of the input amplification stage 412 is coupled to the respective inputs of the output amplification stage 414 and bypass amplification stage 416. The bypass amplification stage 416 includes an output coupled to the negative input of the input amplification stage 412.

The effect of the bypass amplification amplifier 416 is to steer away current from the negative input of the input amplification stage 412 to the output of the bypass amplification stage. As a result, less current resulting from the jammer ends up flowing to the output of the output amplification stage 414 via the feedback capacitor Cfb. Accordingly, the power of a jammer at the output of the output amplification stage 414 is reduced by how much current is steered away by the bypass amplification stage 416. For example, if the bypass amplification stage 416 is configured to steer away half the current away from the input, then the power of a jammer at the output of the output amplification stage 414 is reduced by 6 dB.

Thus, for the case where half the input current is bypassed to the output of the bypass amplification stage 416, the capacitance of the feedback capacitor Cfb may be reduced by half and achieve the same jammer rejection. This results in a net reduction in IC footprint as half the size of the original feedback capacitor Cfb is greater than the additional bypass amplification stage 416. Further, because the feedback capacitor Cfb is now smaller, the output amplification stage 414 may be configured to consume less power.

The current steering capability of the bypass amplification stage 416 may be programmable. For example, if the bypass amplification stage 416 is configured to steer half the current from the input, then the feedback capacitor Cfb may be made twice as small to achieve the same jammer rejection. If, on the other hand, the bypass amplification stage 416 is configured to steer a quarter of the current from the input, then the feedback capacitor Cfb may be configured to be ¾ of the original size to achieve the same jammer rejection. The current steering programmability of the bypass amplification stage amplifier 416 may be accomplished by selecting how many of its amplification transistors are connected in parallel.

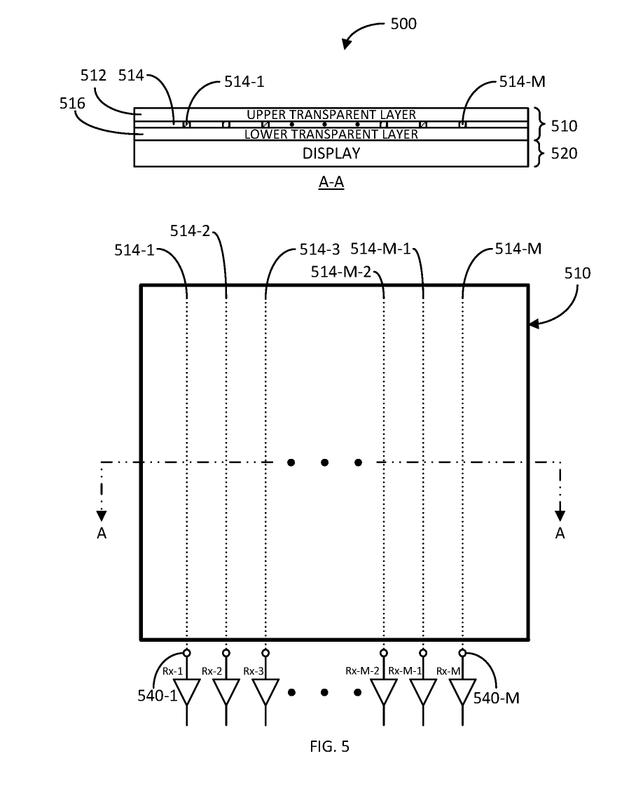

FIG. 5 illustrates a diagram of another touchscreen display 500 in accordance with another aspect of the disclosure. The touchscreen display 500 is similar to touchscreen display 100, but does not include transmit drivers or electrically-conductive transmit lines.

As illustrated in the cross-sectional view A-A, the touchscreen display 500 includes a panel 510 disposed on a display 520. The touchscreen panel 510, in turn, includes a lower transparent layer 516 (e.g., glass) disposed over the display 520, a receive line layer 514 disposed over the lower transparent layer 516, and an upper transparent layer 512 (e.g., glass) disposed over the receive line layer 514.

As better illustrated in the non-cross-sectional view, the receive line layer 514 includes a set of electrically-conductive vertical receive lines 514-1 to 514-M spaced apart along the horizontal direction. As in the other touchscreen display 100, the receive lines 514-1 to 514-M comprise indium-tin-oxide to give them transparent or translucent properties. The touchscreen display 100 further includes a set of receivers Rx-1 to Rx-M coupled to the receive lines 514-1 to 514-M via a set of electrodes 540-1 to 540-M, respectively.

As discussed in more detail herein, the receive lines 540-1 to 540-M capacitively interact with signals generated within the receivers Rx-1 to Rx-M, respectively. When a user places a finger or pointing object on the touchscreen panel 510, the finger or object affects the capacitance of the corresponding receive lines as seen by the input of the corresponding receivers. Accordingly, the corresponding receivers generate signals that are affected by the finger or object, and the remaining receivers generate non-affected signals. Accordingly, a controller (not shown) coupled to the output of the receivers Rx-1 to Rx-M is able to determine the location of the finger or pointing object on the panel 510 based on the signals generated by the receivers Rx-1 to Rx-M.

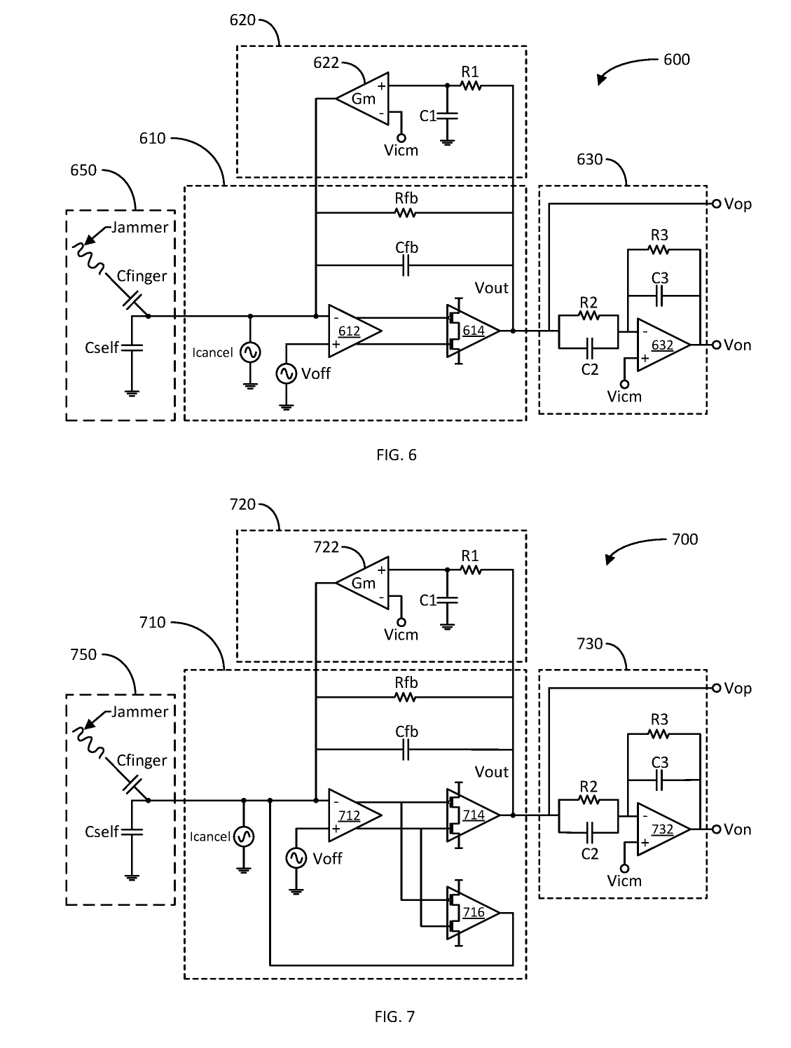

FIG. 6 illustrates a schematic diagram of another exemplary receiver 600 in accordance with another aspect of the disclosure. The receiver 600 may be an exemplary detailed implementation of any of the receivers Rx-1 to Rx-M of touchscreen display 500.

The receiver 600 includes an amplifier 610, a current cancellation circuit 620, and an output circuit 630. A touchscreen panel 650, such as panel 510 previously discussed, is represented as shunt capacitance Cself related to the shunt capacitance associated with the corresponding receive line, electrode, and parasitic capacitance at the input of the receiver 600.

The amplifier 610 includes an input amplification stage 612 followed by an output amplification stage 614, and feedback capacitor Cfb and feedback resistor Rfb coupled in parallel between an output of the amplification stage 614 and a negative input of the input amplification stage 612. Similarly, the input and output amplification stages 612 and 614 may collectively be configured as a class AB amplifier. An offset voltage Voff, which is configured as an oscillating or pulsing voltage, is applied to a positive input of the input amplification stage 612. Due to the feedback operation of the amplifier 610, a signal equivalent to the offset voltage Voff is produced at the negative input of the input amplification stage 612. Ignoring the cancellation current source Icancel for the moment, the amplifier 610 is configured to produce an output voltage Vout given by the following relationship:

Vout=Voff*(1Cself/Cfb) Eq. 1

By derivation of Vout, a change in the output voltage dVout may be calculated based on a change in the self capacitance dCself due to a finger or pointing object interacting with the panel 650; the change in the output voltage dVout may be given by the following relationship:

dVout=Voff*dCself/Cfg Eq. 2

The change in the self-capacitance dCself is an indication that the self-capacitance Cself is being affected by a finger or pointing object on the panel 650. If the offset voltage Voff is large, then the output voltage Vout may cause the amplifier 610 to go into saturation per Eq. 1.

As mentioned above, if the offset voltage Voff is applied to the positive input of the input amplification stage 612, then an equivalent voltage is generated at the negative input of the input amplification stage 612 due to the feedback operation of the amplifier 610. This equivalent voltage produces a current Iself charging or discharging of the self-capacitance Cself and the feedback capacitor Cfb, wherein the value of the current Iself is given as follows:

Iself=(Cself+Cfb)*deriv(Voff) Eq. 3

Accordingly, the current cancellation source Icancel, coupled between the negative input of the input amplification stage 612 and a lower voltage rail (e.g., ground), is configured to generate current to have substantially the same amplitude but 180 degrees out-of-phase with respect to the self-current Iself, so that current cancellation occurs at the negative input of the input amplification stage 612 and the output voltage Vout is substantially midrange (e.g., zero (0) Volt) of the dynamic range (e.g., ±1.8V) of the output voltage Vout during no panel load condition. This allows the full dynamic range of the output of the amplifier 612 to deal with changes in the self-capacitance Cself due to a finger or pointing object being placed on the panel 650 as well as a jammer being introduced into the input of the amplifier 610 via the capacitance Cfinger associated with the user's interaction with the panel.

The cancellation of the self-current Iself by the cancellation current may not be ideal. As a result, some residual current may be present at the negative input of the input amplification stage 612. The amplifier 610, being configured as an integrator, may cause the output voltage Vout to direct current (DC) drift towards saturation due to the residual current at the negative input of the amplifier 610. To counter this, the current cancellation circuit 620 generates or sinks a current based on the output voltage to reduce the residual current at the input of the amplifier 610.

The current cancellation circuit 620 includes a low pass filter including series resistor R1 (e.g., could be realized by a pseudo resistor, such as a switch cap resistor) and shunt capacitor C1 coupled to the output of the amplifier 610. The low pass filter R1/C1 passes the DC component of the output voltage Vout without significantly disturbing the high frequency component of the offset voltage Voff. The current cancellation circuit 620 includes a transconductance (Gm) amplifier 622 including a positive input coupled to an output of the low pass filter R1/C1, a negative input for receiving a voltage Vicm for setting a common mode of a current generated by the transconductance (Gm) amplifier 622, and an output coupled to the negative input of the input amplification stage 612. As the DC component of the output voltage Vout increases or decreases due to residual current, the transconductance (Gm) amplifier 622 generates or sinks a current to counter the residual current to keep the DC component of the output voltage Vout around midrange of the dynamic range of the output voltage Vout.

Similarly, the receiver 600 further includes an output circuit 630 for generating an output differential signal by generating a negative component Von of the differential signal from the output voltage Vout of the amplifier 610. The output voltage Vout of the amplifier 610 serves as the positive component Vop of the differential signal. The output circuit 630 includes an input circuit including resistor R2 coupled in parallel with capacitor C3 between the output of the amplifier 610 and a negative input of an operational amplifier 632. The operational amplifier 632 includes a positive input configured to receive a voltage Vicm for setting a common mode voltage of the negative component Von of the differential signal. The operational amplifier 632 is further configured as an integrator including feedback resistor R3 and feedback capacitor C3 coupled in parallel between the output and negative input of the operational amplifier. The negative component of the output differential signal is produced at the output of the operational amplifier 632.

FIG. 7 illustrates a schematic diagram of yet another exemplary receiver in accordance with another aspect of the disclosure. The receiver 700 may be an exemplary detailed implementation of any of the receivers Rx-1 to Rx-M of touchscreen display 500 previously discussed. The receiver 700 includes an amplifier 710, a current cancellation circuit 720, and an output circuit 730. The receiver 700 includes an input coupled to a touchscreen panel 750. The representation of the touchscreen panel 750, the current cancellation circuit 720 including transconductance (Gm) amplifier 722, and the output circuit 730 including operational amplifier 732 are similar to the corresponding components of receiver 600 previously discussed in detail.

Similar to the amplifier 610, the amplifier 710 includes an input amplification stage 712 and an output amplification stage 714. However, in the case of amplifier 710, it further includes a bypass amplification stage 716. The bypass amplification stage 716 is coupled in parallel with the output amplification stage 714. That is, the output of the input amplification stage 712 is coupled to the respective inputs of the output amplification stage 714 and bypass amplification stage 716. The bypass amplification stage 716 includes an output coupled to the negative input of the input amplification stage 712.

The effect of the bypass amplification amplifier 716 is to steer away current from the negative input of the input amplification stage 712 to the output of the bypass amplification stage. As a result, less current resulting from a jammer ends up flowing to the output of the output amplification stage 714 via the feedback capacitor Cfb. Accordingly, the power of a jammer at the output of the output amplification stage 714 is reduced by how much current is steered away by the bypass amplification stage 716. For example, if the bypass amplification stage 716 is configured to steer away half the current away from the input, then the power of the jammer at the output of the output amplification stage 714 is reduced by 6 dB.

Thus, for the case where half the input current is bypassed to the output of the bypass amplification stage 716, the capacitance of the feedback capacitor Cfb may be reduced by half and achieve the same jammer rejection. This results in a net reduction in IC footprint as half the size of the original feedback capacitor Cfb is greater than the additional bypass amplification stage 716. Further, because the feedback capacitor Cfb is now smaller, the output amplification stage 714 may be configured to consume less power and achieve the same bandwidth. Additionally, because the cancellation current Icancel depends on the feedback capacitor Cfb, a reduction in the size of the feedback capacitor Cfb results in less cancellation current, which leads to further reduction in the power consumption of the receiver 700.

The current steering capability of the bypass amplification stage 716 may be programmable. For example, if the bypass amplification stage 716 is configured to steer half the current from the input, then the feedback capacitor Cfb may be made twice as small to achieve the same jammer rejection. If, on the other hand, the bypass amplification stage 716 is configured to steer a quarter of the current from the input, then the feedback capacitor Cfb may be configured to be ¾ of the original size to achieve the same jammer rejection. The current steering programmability of the bypass amplification stage amplifier 716 may be accomplished by selecting how many of its amplification transistors are connected in parallel.

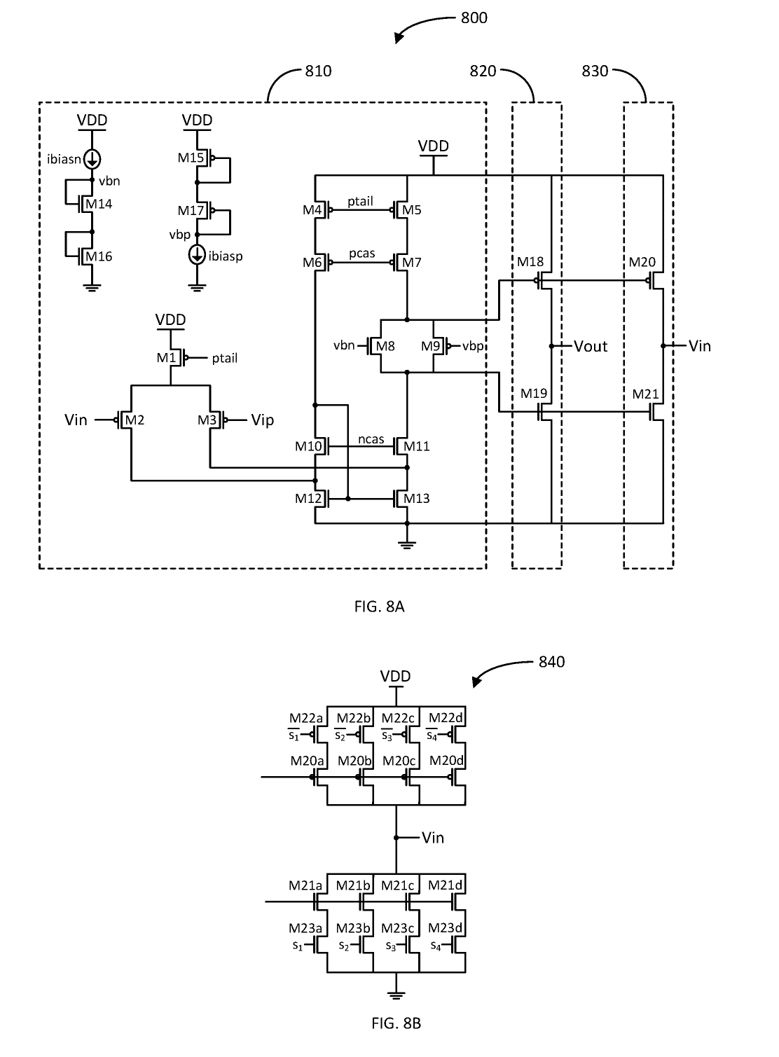

FIG. 8A illustrates a schematic diagram of exemplary amplifier 800 in accordance with another aspect of the disclosure. The amplifier 800 may be an exemplary detailed implementation of the amplifier 410 or 710 previously discussed. As mentioned above, the amplifier 800 is configured as a class AB amplifier. However, it shall be understood that the amplifier 800 may be configured differently.

In particular, the amplifier 800 includes an input amplification stage 810 including transistors M1 to M17 and current sources ibiasn and ibiasp, an output amplification stage 820 including transistors M18 and M19, and a bypass amplification stage 830 including transistors M20 and M21. The transistors M1 to M17 may be configured as metal oxide semiconductor field effect transistors (MOSFETs). The transistors M1 to M7, M9, M15, M17, M18 and M20 are configured as p-channel MOSFETs (referred to herein as “PMOS”) and transistors M8, M10, M11 to M14, M16, M19, and M21 are configured as n-channel MOSFETs (referred to herein as “NMOS”).

With regard to the input amplification stage 810, the transistor M1 is configured as a current source, and includes source and drain coupled between an upper voltage rail VDD and sources of input transistors M2 and M3. The transistor M1 includes a gate configured to receive a ptail bias voltage for setting the current through transistor M1. As mentioned, the transistors M2 and M3 are input transistors including gates configured to receive negative and positive components Vin and Vip of an input differential signal, respectively. With additional reference to FIGS. 4 and 7, the gates of transistors M2 and M3 are examples of the negative and positive inputs of the amplifier 410 and 710, respectively.

The transistors M4, M5, M6, M7, M10, M11, M12, and M13 operate as a current mirror. In particular, the transistors M4, M5, M6, and M7 operate as a p-based cascode active load for the current mirror, and the transistors M10, M11, M12, and M13 operate as an n-based cascode input circuit for the current mirror. Transistors M4, M6, M10, and M12 are coupled in series between the upper voltage rail VDD and a lower voltage rail VSS (e.g., ground). Similarly, transistors M5, M7, parallel-coupled M8 and M9, M11, and M13 are coupled in series between the upper voltage rail VDD and the lower voltage rail VSS (e.g., ground).

The ptail bias voltage is also applied to the gates of transistors M4 and M5. A p-based cascode bias voltage pcas is applied to the gates of transistors M6 and M7. An n-based cascode bias voltage is applied to the gates of transistors M10 and M11. The drain of transistor M6 is coupled to the gates of transistors M12 and M13. The drains of the input transistors M2 and M3 are coupled to the sources of transistors M10 and M11, respectively. A negative-based class AB bias voltage vbn is applied to the gate of transistor M8 and a positive-based class AB bias voltage vbp is applied to the gate of transistor M9.

The negative-based current source ibiasn is coupled in series with diode-connected transistor M14 and diode-connected transistor M16 between the upper voltage rail VDD and the lower voltage rail VSS (e.g., ground). The negative-based class AB bias voltage vbn is generated at a node between the negative-based current source ibiasn and the drain/gate of diode-connected transistor M14.

Similarly, the diode-connected transistor M15 is coupled in series with diode-connected transistor M16 and positive-based current source ibiasp between the upper voltage rail VDD and the lower voltage rail VSS (e.g., ground). The positive-based class AB bias voltage vbp is generated at a node between the drain/gate of diode-connected transistor M17 and the positive-based current source ibiasp.

The output amplification stage 820 includes transistors M18 and M19 coupled in series between the positive voltage rail VDD and the negative voltage rail VSS (e.g., ground). The transistor M19 includes a gate coupled to the drain of transistor M7 (as well as to the drain and source of transistors M8 and M9, respectively). The transistor M19 includes a gate coupled to the drain of transistor M11 (as well as to the source and drain of transistors M8 and M9, respectively). The output amplification stage 820 is configured to generate an output voltage Vout at the node between the drains of transistors M18 and M19.

Similarly, the bypass amplification stage 830 includes transistors M20 and M21 coupled in series between the positive voltage rail VDD and the negative voltage rail VSS (e.g., ground). The transistor M20 includes a gate also coupled to the drain of transistor M7 (as well as to the drain and source of transistors M8 and M9, respectively). The transistor M21 includes a gate also coupled to the drain of transistor M11 (as well as to the source and drain of transistors M8 and M9, respectively). Thus, the bypass amplification stage 830 is coupled in parallel with the output amplification stage 820. The bypass amplification stage 830 includes an output node between the drains of transistors M20 and M21, wherein the output node is coupled to the gate of the input transistor M2. With reference again to FIGS. 4 and 7, the output node of the bypass amplification stage 830 being coupled to the gate of input transistor M2 is an example of the output of bypass amplification stage 416 or 716 coupled to the negative input of the input amplification stage 412 or 712, respectively.

In operation, if the voltage Vin at the gate of transistor M2 is higher than the voltage Vip at the gate of transistor M3, the transistor M3 supplies more of the current from transistor M1 into the drain of transistor M13 than the current supplied by transistor M2 into the drain of transistor M12. Because transistors M12 and M13 have the same gate-to-source voltage (Vgs) and conduct substantially the same current, the additional current supplied to the drain of transistor M13 by transistor M3 causes the current through transistors M8 and M9 to decrease. This causes the voltages at the gate of transistors M18/M19 and transistors M20/M21 to increase. This, in turn, causes the output voltage Vout to decrease because transistor M18 conducts less and transistor M19 conducts more. This also causes transistor M21 to conduct more to sink or steer away more current at the negative input of the amplifier 800 to effectuate the bypass operation previously discussed.

Similarly, if the voltage Vin at the gate of transistor M2 is lower than the voltage Vip at the gate of transistor M3, the transistor M2 supplies more of the current from transistor M1 into the drain of transistor M12 than the current supplied by transistor M3 into the drain of transistor M13. Because transistors M12 and M13 have the same gate-to-source voltage (Vgs) and conduct substantially the same current, the decrease in the current supplied to the drain of transistor M13 by transistor M3 causes the current through transistors M8 and M9 to increase. This causes the voltages at the gate of transistors M18/M19 and transistors M20/M21 to decrease. This, in turn, causes the output voltage Vout to increase because transistor M18 conducts more and transistor M19 conducts less. This also causes transistor M21 to conduct less to sink or steer away less current from the negative input of the amplifier 800 to effectuate the bypass operation based on the lower current at the negative input of the amplifier 800.

The circuits for generating the n-based class AB bias voltage vbn and the p-based class AB bias voltage vbp is for configuring the amplifier 800 for class AB operation, i.e., to reduce distortion of the output voltage Vout when the input differential voltage is substantially zero (0) Volt (i.e., Vip=Vin). In particular, the n-based class AB bias voltage vbn is two (2) diode voltages above ground. Thus, when the input differential voltage is zero (0) Volt, the voltage vbn keeps transistors M19 and M21 slightly conducting. Similarly, the p-based class AB bias voltage vbp is two (2) diode voltages below VDD. Thus, when the input differential voltage is zero (0) Volt, the voltage vbp keeps transistors M19 and M21 slightly conducting. Thus, when the input differential voltage Vip-Vin is crossing zero (0) volt, the transistors M18/M20 and M19/M21 smoothly transition between linear and cutoff regions, or vice-versa.

The current bypassing capability of the bypass amplification stage 830 depends on the ratio M of the size of transistors M18/19 to the size of transistors M20/M21. That is, the ratio of the channel width W₁ and channel length L₁ of transistors M18 and M19 may be configured to be M times the ratio of the channel width W₂ and channel length L₂ of transistors M20 and M21 (e.g., W₁/L₁=M*W₂/L₂). The amount of bypass current Ibp that the bypass amplification stage 830 is able to sink is given by the following equation:

Ibp=Iin*1/(M+1) Eq. 4

Where Iin is the input current at the input of the amplifier 800. Accordingly, the amount of the current Iout that ends up at the output of the amplifier 800 as a result of the bypass operation is given by the following equation:

Iout=Iin−Ibp Eq. 5

Substituting Eq. 4 into Eq. 5, the following equation is derived for the output current Iout as a result of bypass operation:

Iout=Iin−Iin*1/(M+1)=Iin*(1−1/(M+1)) Eq. 6

To achieve the same jammer rejection, the feedback capacitor “new Cfb” as a result of the bypass operation may be determined based on the feedback capacitor “old Cfb” without the bypass operation in accordance with the following relationship:

new Cfb=old Cfb*(1−1/(M+1)) Eq. 7

Considering a couple of examples, if transistors M20 and M21 are configured to have substantially the same size as the transistors M18 and M19 (e.g., M=1), then the bypass current Ibp is ½ of the input current Iin, the output current Iout is also ½ of the input current Iin, and the size of the feedback capacitor new Cfb is ½ the size of the feedback capacitor Cfb without the current bypassing operation to achieve the same jammer rejection. If the transistors M20 and M21 are configured to be ½ the size as the transistors M18 and M19 (e.g., M=2), then the bypass current Ibp is ⅓ of the input current Iin, the output current Iout is also ⅔ of the input current Iin, and the size of the feedback capacitor new Cfb is ⅔ the size of the feedback capacitor Cfb without the current bypassing operation to achieve the same jammer rejection.

FIG. 8B illustrates a schematic diagram of another exemplary bypass amplification stage 840 in accordance with another aspect of the disclosure. The bypass amplification stage 840 may be configured to have a programmable M. This allows the amount of bypass current to be programmable for various applications. The bypass amplification stage 840 may be substituted for the bypass amplification stage 830 in amplifier 800.

The bypass amplification stage 840 includes a set of upper select transistors M22a, M22b, M22c, and M22d coupled in series with a set of upper output transistors M20a, M20b, M20c, and M20d between an upper voltage rail VDD and an output node of the bypass amplification stage, respectively. In this example, these transistors may be configured as PMOSs. The upper select transistors M22a, M22b, M22c, and M22d include gates configured to receive complementary select signals S̅₁̅, S̅₂̅, S̅₃̅, and S̅₄̅, respectively. The gates of the upper output transistors M20a, M20b, M20c, and M20d are coupled to the gate of the upper output transistor M18 of the output amplification stage 820.

The bypass amplification stage 840 includes a set of lower output transistors M21a, M21b, M21c, and M21d coupled in series with a set of lower select transistors M23a, M23b, M23c, and M23d between the output node and a lower voltage rail VSS (e.g., ground). In this example, these transistors may be configured as NMOSs. The lower select transistors M23a, M23b, M23c, and M23d include gates configured to receive select signals S₁, S₂, S₃, and S₄, respectively. The gates of the lower output transistors M21a, M21b, M21c, and M21d are coupled to the gate of the lower output transistor M19 of the output amplification stage 820.

As in bypass amplification stage 830, the output node of bypass amplification stage 840 is also coupled to the negative input of the amplifier 800; specifically, the gate of transistor M2. Each of the output transistors M20a-M20d and M21a-M21d may each be configured to have a size (W₂/L₂) being a defined ratio (e.g., ¼) of the size (e.g., W₁/L₁) of each of the output transistors M18 and M19 of the output amplification stage 820. The select signals S₁/S̅₁̅, S₂/S̅₂̅, S₃/S̅₃̅, and S₄/S̅₄̅ may be configured to change the effective ratio M of the set of output transistors M20a-M20d and M21a-M21d by effectively enabling the corresponding output transistors, respectively.

For example, if the desired ratio M is 4, then the select signals S₁ to S₄ may have a value of {1000}. This particular value of the select signals turns on select transistors M22a and M23a, and turns off select transistors M22b-M22d and M23b-M23d. Thus, only the output transistors M20a and M21a are enabled. Similarly, if the desired ratio M is 2, then the select signals S₁ to S₄ may have a value of {1100}. This particular value of the select signals turns on select transistors M22a-M22b and M23a-M23b, and turns off select transistors M22c-M22d and M23c-M23d. Thus, only the output transistors M20a-M20b and M21a-M21b are enabled. In a like manner, the other desired ratios M=4/3 and M=1 may be achieved with select signals S₁ to S₄ having values {1110} and {1111}, respectively. As discussed above, the ratio M sets the amount bypass current Ibp generated, as well as the capacitance of the feedback capacitor Cfb to maintain the same jammer rejection, as discussed above.

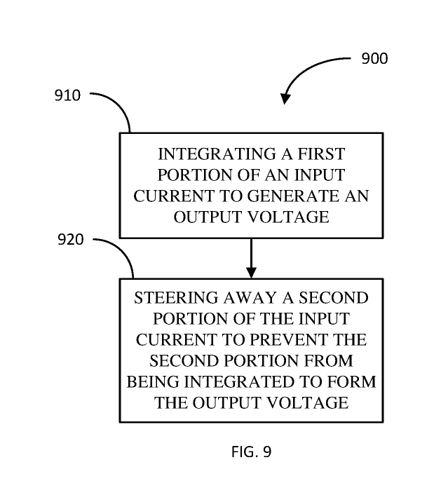

FIG. 9 illustrates a flow diagram of an exemplary method 900 of processing an input current in accordance with another aspect of the disclosure.

The method 900 includes integrating a first portion of the input current to generate an output voltage (block 910). An example of a means for integrating the first portion of the input current includes any of the input amplification stages 412, 712, and 810, any of the output amplification stages 414, 714 and 820, and the feedback capacitor Cfb coupled between an output of the output amplification stage and an input of the first amplification stage.

The method 900 further includes steering away a second portion of the input current to prevent the second portion from being integrated to form the output voltage (block 920). An example of a means for steering away the second portion of the input current includes any of the bypass amplification stages 416, 716, 830, and 840.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. An apparatus, comprising:
a first amplification stage including a first input and a first output;
a second amplification stage including a second input and a second output, wherein the second input is coupled to the first output of the first amplification stage;
a feedback capacitor coupled between the second output of the second amplification stage and the first input of the first amplification stage; and
a third amplification stage including a third input and a third output, wherein the third input is coupled to the first output of the first amplification stage, and the third output is coupled to the first input of the first amplification stage.

2. The apparatus of claim 1, wherein the feedback capacitor is configured to route a first portion of an input current at the first input of the first amplification stage to the second output of the second amplification stage.

3. The apparatus of claim 2, wherein the third amplification stage is configured to steer away a second portion of the input current from the first input of the first amplification stage to the third output of the third amplification stage.

4. The apparatus of claim 3, wherein the third amplification stage is configured steer away the second portion of the input current based on a programmable parameter related to a ratio of the second portion of the input current to the input current.

5. The apparatus of claim 1, wherein the first and second amplification stages are collectively configured as a class AB amplifier.

6. The apparatus of claim 1, further comprising a feedback resistor coupled between the second output of the second amplification stage and the first input of the first amplification stage.

7. The apparatus of claim 1, further comprising a touchscreen panel including an electrically-conductive line coupled to the first input of the first amplification stage.

8. The apparatus of claim 1, further comprising a current cancellation circuit configured to remove charges from a shunt capacitance at the first input of the first cancellation stage based on an output voltage produced at the second output of the second amplification stage.

9. The apparatus of claim 8, wherein the current cancellation circuit comprises:
a low-pass filter configured to filter the output voltage from the second output of the second amplification stage;
a transconductance amplifier configured to generate a current based on filtered output voltage; and
a current source configured to remove the charges from the shunt capacitance based on the current generated by the transconductance amplifier.

10. The apparatus of claim 1, wherein the second amplification stage is configured to generate a positive component of an output differential signal, and further comprising an output circuit configured to generate a negative component of the output differential signal based on the positive component.

11. A method comprising:
integrating a first portion of an input current to generate an output voltage; and
steering away a second portion of the input current to prevent the second portion from being integrated to form the output voltage.

12. The method of claim 11, wherein integrating the first portion of the input current comprises applying the first portion of the input current to an integrator including a first amplification stage followed by a second amplification stage, and a feedback capacitor coupled between an output of the second amplification stage and an input of the first amplification stage.

13. The method of claim 12, wherein steering away the second portion of the input current comprises applying the second portion to an output of a third amplification stage, wherein the third amplification stage includes an input coupled to an output of the first amplification stage.

14. The method of claim 11, further comprising generating the input current in response to a drive voltage being applied to touchscreen panel.

15. The method of claim 11, further comprising controlling an amount of the second portion of the input current with respect to an amount of the first portion of the input current.

16. An apparatus comprising:
means for integrating a first portion of an input current to generate an output voltage; and
means for steering away a second portion of the input current to prevent the second portion from being integrated to form the output voltage.

17. The apparatus of claim 16, wherein the means for integrating the first portion of the input current comprises a first amplification stage followed by a second amplification stage, and a feedback capacitor coupled between an output of the second amplification stage and an input of the first amplification stage.

18. The apparatus of claim 17, wherein the means for steering away the second portion of the input current comprises a third amplification stage including an input coupled to an output of the first amplification stage, and an output coupled to the input of the first amplification stage.

19. The apparatus of claim 16, further comprising means for generating the input current comprising means for generating a drive voltage applied to at least one electrically-conductive line of a touchscreen panel.

20. The apparatus of claim 16, further comprising means for controlling an amount of the second portion of the input current with respect to an amount of the first portion of the input current.
